(19) United States
(12) Patent Application Publication
(10) Pub. No.: US 2026/0080925 A1
(43) Pub. Date: Mar. 19, 2026

(54) NONVOLATILE MEMORY DEVICE INCLUDING FERROELECTRIC CELL CAPACITOR AND OPERATING METHOD THEREOF

(71) Applicant: SAMSUNG ELECTRONICS CO., LTD., Suwon-si (KR)

(72) Inventors: Sunggyeong LEE, Suwon-si (KR); Hyunchul HOON, Suwon-si (KR)

(73) Assignee: SAMSUNG ELECTRONICS CO., LTD., Suwon-si (KR)

(21) Appl. No.: 19/174,557

(22) Filed: Apr. 9, 2025

(30) Foreign Application Priority Data
Sep. 19, 2024 (KR) 10-2024-0126720

(51) Int. Cl. G11C 11/22

(52) U.S. Cl. CPC G11C 11/221; G11C 11/2255; G11C 11/2257; G11C 11/2259

(57) ABSTRACT

Provided are a nonvolatile memory device including a ferroelectric cell capacitor and an operating method of the nonvolatile memory device. The nonvolatile memory device includes a memory cell array including a first memory cell and a second memory cell, the first memory cell and second memory cell being connected to a selected word line corresponding to an address among a plurality of word lines, a first local plate line driver extending in a first direction in which the plurality of word lines extend and connected to a plurality of first local plate lines parallel to the plurality of word lines, and a second local plate line driver extending in the first direction and connected to a plurality of second local plate lines that are apart from the plurality of first local plate lines in the first direction.

### CROSS-REFERENCE TO RELATED APPLICATION

This application is based on and claims to Korean Patent Application No. 10-2024-0126720, filed on Sep. 19, 2024, in the Korean Intellectual Property Office, the disclosure of which is incorporated by reference herein in its entirety.

### BACKGROUND

### 1. Field

The disclosure relates to electronic devices, and more particularly, to a nonvolatile memory device including a ferroelectric cell capacitor, and an operating method of the nonvolatile memory device.

### 2. Description of Related Art

With the recent advancement of high-speed and low-power electronic products, fast read/write operations and low operating voltages of semiconductor devices embedded in electronic products have been required. In response to these demands, research has been conducted on ferroelectric memories having ferroelectricity in which internal electric dipole moments are aligned and spontaneous polarization is maintained even if no external electric field is applied. In particular, highly integrated ferroelectric memory has emerged as a next-generation memory because it enables high-speed read and write operations and is nonvolatile.

### SUMMARY

Provided is nonvolatile memory device including a ferroelectric cell capacitor for improving data reliability and reducing power consumption and a method of operating the nonvolatile memory device.

According to an aspect of the disclosure, a nonvolatile memory device includes: a memory cell array including a first memory cell and a second memory cell, wherein the first memory cell and the second memory cell are connected to a selected word line among a plurality of word lines, wherein the selected word line corresponds to an address, and wherein the plurality of word lines extend in a first direction; a first local plate line driver connected to a plurality of first local plate lines, wherein the plurality of first local plate lines extend in the first direction; and a second local plate line driver connected to a plurality of second local plate lines, wherein the plurality of second local plate lines extend in the first direction and are separated from the plurality of first local plate lines in the first direction, wherein the first memory cell is connected to a first bit line among a plurality of bit lines and to the plurality of first local plate lines, and wherein the second memory cell is connected to a second bit line among the plurality of bit lines and to the plurality of second local plate lines.

According to an aspect of the disclosure, a nonvolatile memory device includes: a memory cell array including a first memory cell and a second memory cell, wherein the first memory cell and the second memory cell are connected to a first bit line among a plurality of bit lines, and wherein the plurality of bit lines extend in a first direction; a first local plate line driver connected to a plurality of first local plate lines, wherein the plurality of first local plate lines extend in the first direction; and a second local plate line driver connected to a plurality of second local plate lines, wherein the plurality of second local plate lines extend in the first direction and are separated from the plurality of first local plate lines in the first direction, wherein the first memory cell is connected to a selected word line among a plurality of word lines and to the plurality of first local plate lines, wherein the selected word line corresponds to an address, and wherein the second memory cell is connected to a first unselected word line among the plurality of word lines and to the plurality of second local plate lines.

According to an aspect of the disclosure, a method of operating a nonvolatile memory device including a plurality of memory cells includes: applying a first voltage to a selected first local plate line, from among a plurality of first local plate lines of the nonvolatile memory device, wherein the plurality of first local plate lines extend in a first direction and are connected to a first memory cell among the plurality of memory cells; applying a second voltage lower than the first voltage to a first unselected plate line, from among the plurality of first local plate lines; and applying the second voltage to a plurality of second local plate lines of the nonvolatile memory device, wherein the plurality of second local plate lines extend in the first direction and are separated from the plurality of first local plate lines in the first direction.

According to the disclosure, the operating performance nonvolatile memory devices may be improved by reducing disturbance of the amount of charge charged in an unselected ferroelectric cell capacitor.

In addition, power consumption may be reduced by reducing disturbance of the amount of charge charged in an unselected ferroelectric cell capacitor.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a block diagram of a nonvolatile memory device according to one or more embodiments;

FIG. 2 is a diagram illustrating a ferroelectric cell capacitor according to one or more embodiments;

FIG. 3 is a circuit diagram of a memory cell and a sense amplifier, according to one or more embodiments;

FIG. 4 is a diagram illustrating a memory cell array including the memory cell of FIG. 3 and local plate lines and word lines that are parallel to each other;

FIGS. 5 and 6 are timing diagrams of signals for performing a read operation in the embodiment of FIG. 4;

FIGS. 7 and 8 are timing diagrams of signals for performing a write operation in the embodiment of FIG. 4;

FIG. 9 is a timing diagram of signals for performing a write operation, according to one or more embodiments;

FIG. 10 is a diagram illustrating a memory cell array including the memory cell of FIG. 3 and local plate lines and bit lines that are parallel to each other;

FIG. 11 is a timing diagram of signals for performing a read operation in the embodiment of FIG. 10;

FIG. 12 is a timing diagram of signals for performing a write operation in the embodiment of FIG. 10;

FIG. 13 is a circuit diagram of a memory cell, a bit line driver, and a sense amplifier, according to one or more embodiments;

FIG. 14 is a diagram illustrating a memory cell array including the memory cell of FIG. 13 and local plate lines and bit lines that are parallel to each other;

FIG. 15 is a timing diagram of signals for performing a read operation in the embodiment of FIG. 14;

FIG. 16 is a timing diagram of signals for performing a write operation in the embodiment of FIG. 14; and

FIG. 17 is a flowchart of an operating method of a nonvolatile memory device, according to one or more embodiments.

### DETAILED DESCRIPTION

Hereinafter, one or more embodiments are described in detail with reference to the accompanying drawings.

Expressions such as “first,” “second,” etc. used herein may represent various elements regardless of order and/or importance and are only used to distinguish one component from other components and do not limit the components. For example, a first user device and a second user device may represent different user devices regardless of order or importance. For example, a first element may be named as a second element without departing from the scope of the one or more embodiments of the present disclosure, and similarly, a second element may be named as a first element.

When it is described that an element (such as a first element) is “operatively or communicatively coupled with/to” or “connected” to another element (such as a second element), the element may be directly connected to the other element or may be connected to the other element through another element (e.g., a third element). However, when it is described that an element (such as a first element) is “directly connected” or “directly coupled” to another element (such as a second element), it means that there is no intermediate element (such as a third element) between the element and the other element.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block”may include a plurality of components.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

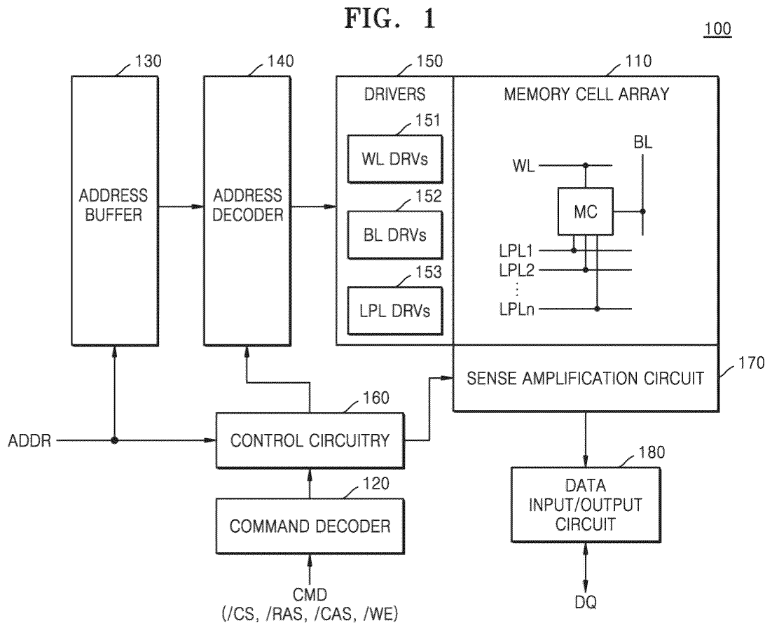

FIG. 1 is a nonvolatile memory device 100 according to one or more embodiments.

Referring to FIG. 1, the nonvolatile memory device 100 may include a memory cell array 110, a command decoder 120, an address buffer 130, an address decoder 140, drivers 150, a control circuit (or control circuitry) 160, a sense amplification circuit 170, and a data input/output circuit 180.

The nonvolatile memory device 100 may be a ferroelectric random access memory (FeRAM) that detects cell voltage stored in a memory cell MC as data. Here, FeRAM may also be referred to as FRAM.

The nonvolatile memory device 100 may input and output data DQ in response to a command CMD and an address ADDR received from an external device (e.g., a central processing unit (CPU)) or a memory controller).

The memory cell array 110 may include a plurality of memory cells. The memory cell array 110 may include a plurality of word lines, a plurality of bit lines, and a plurality of plate lines connected to the memory cells. In one or more embodiments, each of the plurality of plate lines may include a plurality of local plate lines. A local plate line may be a plate line that is connected to some of the memory cells.

A memory cell MC may be connected to a word line WL, a bit line BL, and n local plate lines LPL1 to LPLn. n may be an integer greater than or equal to 2. Each memory cell may include at least one cell transistor and at least two ferroelectric cell capacitors. The memory cell MC may store a cell voltage having a value that specifies the data DQ in a ferroelectric cell capacitor. Depending on the number of p cell transistors and q ferroelectric cell capacitors, the memory cell MC may have a structure of pTqC. Here, in pTqC, “T” refers to the cell transistor and “C” refers to the ferroelectric cell capacitor. Here, the number of ferroelectric cell capacitors may correspond to the number of local plate lines. For example, when the memory cell MC has a 1T2C structure, the memory cell MC may include one cell transistor and two ferroelectric cell capacitors and may be connected to two local plate lines (e.g., LPL1, LPL2). For example, when the memory cell MC has a 2T2C structure, the memory cell MC may include two cell transistors and two ferroelectric cell capacitors and may be connected to two local plate lines. However, the disclosure is not limited to the examples described above.

In one or more embodiments, when the memory cell MC includes two cell transistors, the memory cell array 110 may further include a plurality of read bit lines. In this case, a plurality of bit lines included in the memory cell array 110 may be used to transfer the data DQ to the memory cell array 110 during a write operation. A plurality of read bit lines included in the memory cell array 110 may be used to transfer the data DQ stored in the memory cell MC to the sense amplification circuit 170 during a read operation.

The command decoder 120 may determine an input command CMD by referring to a chip select signal /S, a row address strobe signal /AS, a column address strobe signal /AS, a write enable signal /E, etc., applied from an external device. That is, detailed information of the command CMD may be determined by a combination of logic levels of the chip select signal /S, row address strobe signal /AS, column address strobe signal /AS, and write enable signal /E. The command decoder 120 may generate control signals corresponding to the command CMD. The command CMD may include an active command, a read command, a write command, a precharge command, etc.

The address buffer 130 receives the address ADDR applied from an external device. The address ADDR may include a word line address addressing a word line, a bit line address addressing at least one bit line, and a plate address addressing at least one local plate line. The address buffer 130 may transmit each of the word line address, the bit line address, and the plate line address to the address decoder 140.

The address decoder 140 may select the word line WL, bit line BL, and a local plate line from among n local plate lines LPL1 to LPLn, connected to the memory cell MC to be accessed in response to the address ADDR. In one or more embodiments, the address decoder 140 may include a word line decoder, a bit line decoder, and a plate line decoder.

The word line decoder may decode a word line address and select the word line WL of a memory cell MC corresponding to the word line address. The bit line decoder may decode a bit line address and select the bit line BL of a memory cell MC corresponding to the bit line address. The plate line decoder may decode a plate line address to select the local plate line PL of a memory cell MC corresponding to the local plate line address.

The drivers 150 may drive a plurality of word lines, a plurality of bit lines, and n local plate lines LPL1 to LPLn. In one or more embodiments, the drivers 150 may include word line drivers 151, bit line drivers 152, and local plate line drivers 153.

Word line drivers 151 may apply word line voltages to the plurality of word lines. In one or more embodiments, a word line driver selected by a word line decoder among the word line drivers 151 may apply an activation voltage having an activation level to a selected word line to activate the selected word line from among the plurality of word lines. In addition, unselected word line drivers may apply a deactivation voltage to the unselected word lines.

The bit line drivers 152 may provide a voltage corresponding to the data DQ to at least one bit line selected from among the plurality of bit lines. In one or more embodiments, at least one bit line driver selected by a bit line decoder among the bit line drivers 152 may apply the voltage corresponding to the data DQ to at least one bit line selected from among the plurality of bit lines.

The local plate line drivers 153 may apply plate line voltages to the local plate lines. In one or more embodiments, a selected local plate line driver among the local plate line drivers 153 may apply a first voltage to a selected local plate line among the n local plate lines LPL1 to LPLn and may apply a second voltage to unselected local plate lines among the n local plate lines LPL1 to LPLn. In one or more embodiments, unselected local plate line drivers 153 among the local plate line drivers may apply a second voltage and/or a third voltage to local plate lines connected to each of the unselected memory cells among the memory cells.

The control circuit 160 may control the sense amplification circuit 170 according to the command CMD decoded by the command decoder 120. The control circuit 160 may control the operation of the sense amplification circuit 170 to detect a cell voltage of the memory cell MC. The control circuit 160 may control the sense amplification circuit 170 to perform a precharge operation, a charge sharing operation, a detection operation, etc.

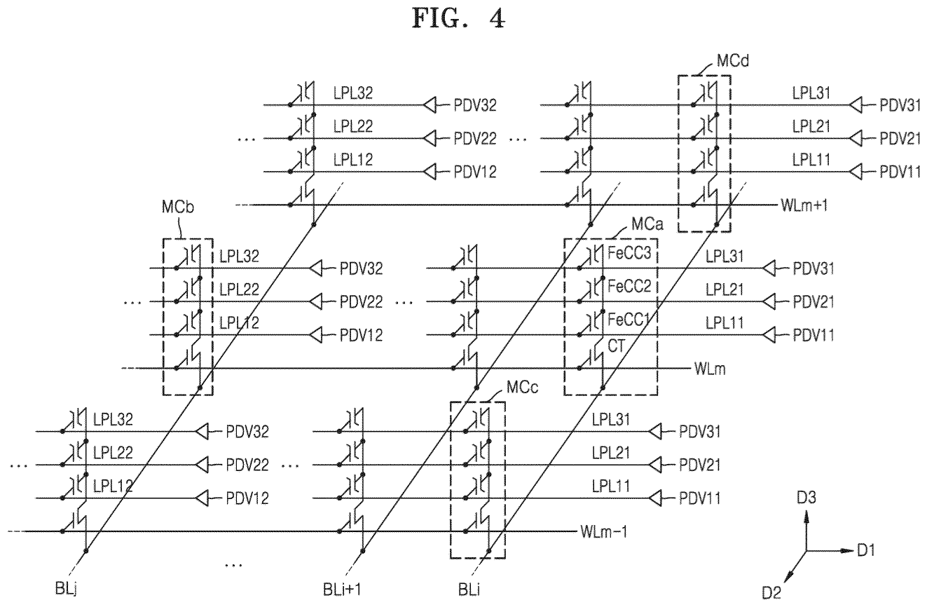

The control circuit 160 may store information on the selected word line on which the current operation is being performed based on the address ADDR. The control circuit 160 may control the operation of the address decoder 140 to select local plate line drivers 153 based on the information of the stored word line. The operation of selecting local plate line drivers 153 is described below with reference to FIGS. 4 to 12 and FIGS. 14 to 16.

The sense amplification circuit 170 may detect the charge stored in the memory cell MC as data. In addition, the sense amplification circuit 170 may transmit the data DQ to the data input/output circuit 180 so that the detected data DQ is output to the outside of the nonvolatile memory device 100 through data pad(s). The sense amplification circuit 170 may be referred to as a bit line sense amplifier (BLSA).

The data input/output circuit 180 may receive the data DQ to be written to the memory cells from the outside and transmit the data DQ to the memory cell array 110. The data input/output circuit 180 may output bit data detected by the sense amplification circuit 170 as read data to the outside through the data pad(s).

According to one or more embodiments, the operating performance may be improved by reducing disturbance of the amount of charge charged in an unselected ferroelectric cell capacitor.

In addition, according to one or more embodiments, power consumption may be reduced by reducing disturbance of the amount of charge charged in the unselected ferroelectric cell capacitor.

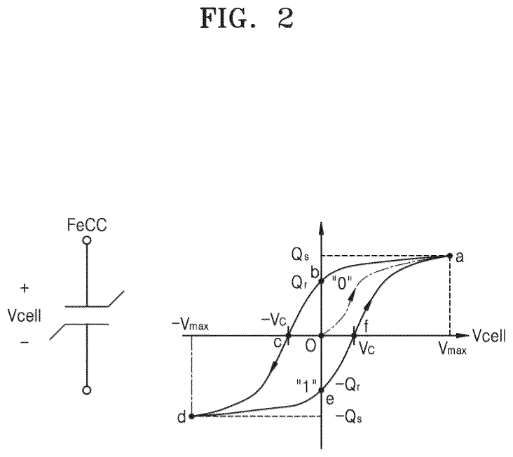

FIG. 2 is a diagram illustrating a ferroelectric cell capacitor FeCC according to one or more embodiments.

Referring to FIG. 2, the ferroelectric cell capacitor FeCC may include a material having ferroelectricity. Here, the ferroelectric cell capacitor FeCC, as a material having ferroelectricity, may include, but is not limited to, lead zirconate titanate (PZT), lanthanum-modified lead zirconate titanate (PLZT), bismuth lanthanum titanate (BLT), barium strontium titanate (BST), strontium bismuth tantalate (SBT), or combinations thereof. In addition, the ferroelectric cell capacitor FeCC may include at least one of, for example, hafnium oxide, hafnium zirconium oxide, zirconium oxide, barium strontium titanium oxide, barium titanium oxide, and lead zirconium titanium oxide.

The hysteresis loop characteristic of the ferroelectric cell capacitor FeCC is shown in FIG. 2. Here, Qᵣ represents a remnant charge, Qₛ represents a saturation charge, and Vc represents a coercive voltage. The coercive voltage represents a voltage size that forms the total charge Q of the ferroelectric cell capacitor FeCC to 0 Coulomb [C], and the residual charge and saturation charge are described below.

In the initial state of the ferroelectric cell capacitor FeCC, the cell voltage Vcell may be 0 V. The initial state of the ferroelectric cell capacitor FeCC is shown at point O in FIG. 2.

When the level of the cell voltage Vcell applied to the ferroelectric cell capacitor FeCC gradually increases from the initial state of the point O, polarization may occur in the ferroelectric cell capacitor FeCC as shown in the dashed line in FIG. 2, and the total charge Q of the ferroelectric cell capacitor FeCC may increase to Qs (point a). Here, the state at point a at which the voltage level of the voltage applied to the ferroelectric cell capacitor FeCC is greater than a voltage level of the first voltage may be referred to as saturation polarization of the ferroelectric cell capacitor FeCC. Here, the voltage level of the first voltage may be Vmax.

When the voltage level of the voltage applied to the ferroelectric cell capacitor FeCC decreases in the saturation polarization state (e.g., at point a), the total charge Q of the ferroelectric cell capacitor FeCC may decrease along the upper solid line instead of along the dashed line in reverse (from point a to point b). At point b shown in FIG. 2, although the voltage level of the voltage applied to the ferroelectric cell capacitor FeCC is 0 V, the total charge Q of the ferroelectric cell capacitor FeCC has a finite value, Qr, which is not 0 [C], and Qr may be referred to as the residual charge.

At point b, when a voltage having a negative level (i.e., a reverse voltage) is applied to the ferroelectric cell capacitor FeCC and the magnitude of the reverse voltage gradually increases, the total charge Q of the ferroelectric cell capacitor FeCC may pass through point c at which the total charge Q of the ferroelectric cell capacitor FeCC becomes 0 [C] and a polarization in the opposite direction occurs, so that the total charge Q of the ferroelectric cell capacitor FeCC may be saturated at −Qs (point d).

When the magnitude of the reverse voltage applied to the ferroelectric cell capacitor FeCC decreases at a saturation polarization state (e.g., at point d), the total charge Q of the ferroelectric cell capacitor FeCC reaches point e, and when the magnitude of a forward voltage increases so that the total charge Q of the ferroelectric cell capacitor FeCC passes through point e, the total charge Q of the ferroelectric cell capacitor FeCC may move along the solid line (i.e., solid line defa) connecting points d, e, f, and a.

That is, the total charge Q of the ferroelectric cell capacitor FeCC corresponding to the voltage level of the voltage applied to one ferroelectric cell capacitor FeCC may correspond to two solid lines (i.e., solid line abcd and solid line defa). This change in value depending on the history of the process may be referred to as a history loop characteristic. Here, the extent to which the total charge Q of the ferroelectric cell capacitor FeCC moves along the two solid lines may be referred to as disturbance.

When a read operation or a write operation is performed, the total charge of a selected ferroelectric cell capacitor among a plurality of ferroelectric cell capacitors included in a selected memory cell may move along the two solid lines. It is important that the disturbance of unselected ferroelectric cell capacitors among the ferroelectric cell capacitors included in the selected memory cell is made as small as possible, and it is also important that the disturbance of the ferroelectric cell capacitors included in the unselected memory cells is made as small as possible.

When the total charge Q of the ferroelectric cell capacitor FeCC is Qr corresponding to point b or −Qr corresponding to point e, the ferroelectric cell capacitor FeCC may be in a stable state.

Hereinafter, it is assumed that when the voltage level of the voltage applied to the ferroelectric cell capacitor FeCC is 0 V, the total charge Q of the ferroelectric cell capacitor FeCC is one of Qr indicating data “0 ” (or a bit value “0”) and −Qr indicating data “1”. That is, it is assumed that the ferroelectric cell capacitor FeCC is in a stable state. In one or more embodiments, a case in which the total charge Q of the ferroelectric cell capacitor FeCC is −Qr may correspond to data “0”, and a case in which the total charge Q of the ferroelectric cell capacitor FeCC is Qr may correspond to data “1”, but the disclosure is not limited thereto.

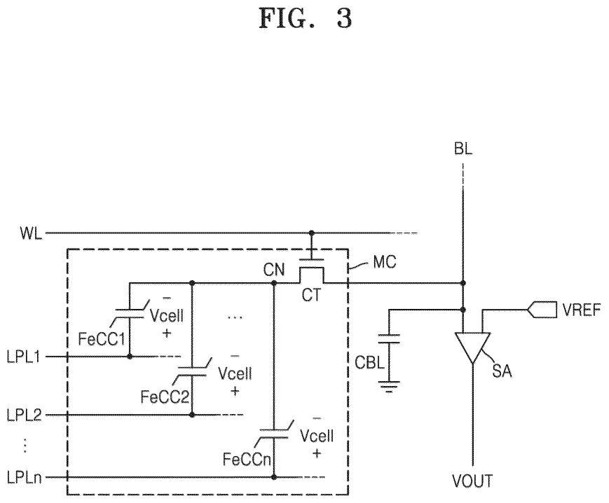

FIG. 3 is a circuit diagram of a memory cell MC and a sense amplifier SA according to one or more embodiments.

Referring to FIG. 3, the memory cell MC according to one or more embodiments may have a structure of 1TnC and may include a cell transistor CT and n ferroelectric cell capacitors FeCC1 to FeCCn.

The cell transistor CT may be turned on in response to the word line WL being activated, and the turned-on cell transistor CT may electrically connect the bit line BL to a node CN. A gate electrode of the cell transistor CT may be connected to the word line WL, and the cell transistor CT may be connected between the bit line BL and the node CN. For example, a first terminal (or a first electrode) of the cell transistor CT may be connected to the bit line BL. A second terminal (or a second electrode) of the cell transistor CT may be connected to the node CN. In one or more embodiments, the cell transistor CT may be implemented as an n-type transistor, such as an N-type metal-oxide-semiconductor (NMOS) transistor. However, the disclosure is not limited to the embodiments described above.

A set of n ferroelectric cell capacitors FeCC1 to FeCCn may store charges corresponding to the capacity of data. The n ferroelectric cell capacitors FeCC1 to FeCCn may be connected between the node CN and n local plate lines LPL1 to LPLn. For example, a first terminal of the n ferroelectric cell capacitors FeCC1 to FeCCn may be connected to the node CN. A second terminal of each of the n ferroelectric cell capacitors FeCC1 to FeCCn may be connected to a corresponding local plate line among the n local plate lines LPL1 to LPLn. For example, the first ferroelectric cell capacitor FeCC1 may be connected between the node CN and the first local plate line LPL1. The second ferroelectric cell capacitor FeCC2 may be connected between the node CN and the second local plate line LPL2. Similarly, the n-th ferroelectric cell capacitor FeCCn may be connected between the node CN and the n-th local plate line LPLn. The cell voltage Vcell may be generated in each of the n ferroelectric cell capacitors FeCC1 to FeCCn.

The sense amplification circuit 170 may include a sense amplifier SA. Referring to FIG. 3, for convenience of description, an equivalent circuit of the sense amplification circuit 170 may include the sense amplifier SA and a parasitic capacitor CBL having the total parasitic capacitance of the bit line BL connected to the corresponding memory cell MC.

A first terminal of the parasitic capacitor CBL and a first input terminal of the sense amplifier SA may be connected to the first terminal of the cell transistor CT and the bit line BL. A second terminal of the parasitic capacitor CBL may be connected to the ground. A second input terminal of the sense amplifier SA may be connected to a terminal to which a reference voltage VREF is applied. The reference voltage VREF may be generated by the control circuit 160.

When a read operation is performed, the sense amplifier SA may compare voltage levels of the reference voltage VREF and a voltage applied to the parasitic capacitor CBL and output an output voltage VOUT corresponding to data stored in the memory cell MC.

In one or more embodiments, the sense amplifier SA may output the output voltage VOUT of a first voltage level corresponding to data “1” stored in the memory cell MC when the voltage level of the voltage applied to the parasitic capacitor CBL is greater than that of the reference voltage VREF. In addition, the sense amplifier SA may output an output voltage VOUT of a second voltage level corresponding to data “0 ” stored in the memory cell MC when the voltage level of the voltage applied to the parasitic capacitor CBL is lower than that of the reference voltage VREF. Here, the first voltage level may be greater than the second voltage level. However, depending on the embodiment, the first voltage level may be lower than the second voltage level, but the disclosure is not limited thereto.

In one or more embodiments, local plate lines LPL1 to LPLn connected to the memory cell MC may be parallel to a plurality of word lines including the word line WL. Memory cells in a structure in which local plate lines LPL1 to LPLn are parallel to the word line WL are described below with reference to FIG. 4.

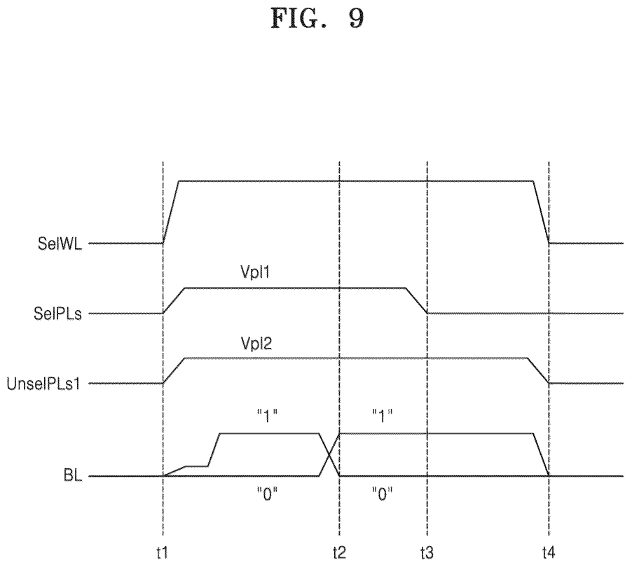

In one or more embodiments, local plate lines LPL1 to LPLn connected to the memory cell MC may be parallel to a plurality of bit lines including the bit line BL. Memory cells in a structure in which n local plate lines LPL1 to LPLn are parallel to the bit line BL are described below with reference to FIG. 9.

FIG. 4 is a diagram illustrating the memory cell array 110 including the memory cell MC of FIG. 3 and local plate lines and word lines that are parallel to each other.

Referring to FIGS. 1 and 4, in one or more embodiments, the memory cell array 110 may include a plurality of word lines WLm−1, WLm, and WLm+1 extending in a first direction D1, a plurality of bit lines BLi, BLi+1, and BLj extending in a second direction D2, and a plurality of local plate lines LPL11, LPL12, LPL21, LPL22, LPL31, and LPL32 extending in the first direction D1. In FIG. 4, m is an integer greater than or equal to 2, and i and j may be different arbitrary integers. The number of each line in FIG. 4 is an example and may be greater than that shown in FIG. 4. The word lines WLm−1, WLm, and WLm+1 may be arranged in parallel in the second direction D2. The word line WLm may be adjacent to the word lines WLm−1 and WLm+1. The bit lines BLi, BLi+1, and BLj may be arranged in parallel in the first direction D1. The bit lines BLi and BLi+1 may be adjacent to each other. The local plate lines LPL11, LPL12, LPL21, LPL22, LPL31, and LPL32 may be arranged in parallel in a third direction D3.

In one or more embodiments, the memory cell array 110 may include a plurality of memory cells, each of which may have a 1TnC structure as described above with reference to FIG. 3. Each memory cell has a 1T3C structure and may include one cell transistor CT and three ferroelectric cell capacitors FeCC1, FeCC2, and FeCC3. Although three ferroelectric cell capacitors FeCC1, FeCC2, and FeCC3 are illustrated in FIG. 4, each of the memory cells may include two or four or more ferroelectric cell capacitors. In the following, it is assumed that each memory cell includes three ferroelectric cell capacitors FeCC1, FeCC2, and FeCC3.

In one or more embodiments, the memory cell array 110 may include a first memory cell and a second memory cell connected to a selected word line corresponding to the address ADDR among the word lines WLm−1, WLm, and WLm+1. The first memory cell may be connected to any one of the bit lines BLi, BLi+1, and BLj and some local plate lines. The local plate lines connected to the first memory cell may be referred to as first local plate lines. The second memory cell may be connected to another bit line among the bit lines BLi, BLi+1 and BLj and to some local plate lines other than the first local plate lines. The local plate lines connected to the second memory cell may be referred to as second local plate lines. For example, when the selected word line is a word line WLm, the first memory cell may be a memory cell MCa and the second memory cell may be a memory cell MCb. The memory cell MCa may be connected to the bit line BLi and the local plate lines LPL11, LPL21, and LPL31. The bit line BLi may also be referred to as a first bit line. The memory cell MCb may be connected to the bit line BLj and the local plate lines LPL12, LPL22, and LPL32. The bit line BLj may also be referred to as a second bit line.

The first memory cell may include a first cell transistor and first ferroelectric cell capacitors. The first cell transistor may have a gate electrode connected to a selected word line (e.g., the word line WLm) and may be connected between the first bit line (e.g., the bit line BLi) and the first node (e.g., the node CN). The first ferroelectric cell capacitors may be connected between the first node and the first local plate lines (e.g., the local plate lines LPL11, LPL21, and LPL31). The second memory cell may include second cell transistors and second ferroelectric cell capacitors. The second cell transistor may have a gate electrode connected to a selected word line (e.g., the word line WLm) and may be connected between the second bit line (e.g., the bit line BLj) and the second node (e.g., node CN). The second ferroelectric cell capacitors may be connected between the second node and the second local plate lines (e.g., the local plate lines LPL12, LPL22, and LPL32).

In one or more embodiments, the local plate line drivers 153 may include at least two local plate line drivers for one word line. For example, the local plate line drivers 153 may include first and second local plate line drivers for each word line. The number of memory cells supplied with voltage by the first local plate line driver may be one or more. Similarly, the number of memory cells supplied with voltage by the second local plate line driver may be one or more.

The first local plate line driver may be connected to local plate lines connected to the first memory cell, and the local plate lines connected to the first memory cell may extend in a direction (e.g., the first direction D1) in which the word lines WLm−1, WLm, and WLm+1 extend and may be arranged parallel to the plurality of word lines WLm−1, WLm, and WLm+1. For example, when the first memory cell is the memory cell MCa, the first local plate line driver may include sub-plate line drivers PDV11, PDV21, and PDV31 connected to local plate lines LPL11, LPL21, and LPL31.

The second local plate line driver may be connected to local plate lines connected to the second memory cell, and the local plate lines connected to the second memory cell may extend in a direction (e.g., the first direction D1) in which the plurality of word lines WLm−1, WLm, and WLm+1 extend and may be arranged to be apart from the local plate lines connected to the first memory cell. For example, when the first memory cell is the memory cell MCa and the second memory cell is the memory cell MCb, the second local plate line driver may include sub-plate line drivers PDV12, PDV22, and PDV32 connected to local plate lines LPL12, LPL22, and LPL32.

In a structure in which each word line is parallel to each local plate line as illustrated in FIG. 4, the voltage provided to the local plate line may be applied equally to data “1” and data “0”. In addition, two or more memory cells (e.g., MCa, MCb, etc.) connected to a selected word line are selected, and the first local plate line and the second local plate line, which are arranged at the same position in the third direction D3 among the first local plate lines and the second local plate lines, are selected. A voltage having a predefined voltage level (e.g., the first voltage corresponding to Vmax) may be applied to the selected first local plate line and the selected second local plate line. The disturbance of the ferroelectric cell capacitors connected to the selected first local plate line and the selected second local plate line may have a range from 0 V to Vmax, from 0 V to −Vmax, or from Vmax to −Vmax. However, parasitic capacitors, etc. may exist between the selected local plate lines and the unselected local plate lines. Accordingly, the voltage levels of the unselected local plate lines may be changed as the first voltage is applied to each of the selected local plate lines. Therefore, unintentional excessive disturbance may occur in the ferroelectric cell capacitors connected to the unselected local plate lines, and the total charge of the corresponding ferroelectric cell capacitors may be changed.

In one or more embodiments, the first local plate line driver may apply the first voltage to the selected first local plate line corresponding to the address ADDR among the first local plate lines. In addition, the first local plate line driver may apply the second voltage to at least one unselected first local plate line. For example, referring to FIG. 4, when the first memory cell is the memory cell MCa and the selected first local plate line is the local plate line LPL31 connected to the memory cell MCa, the sub-plate line driver PDV31 may apply the first voltage to the local plate line LPL31 and the sub-plate line drivers PDV11 and PDV21 may apply the second voltage to the local plate lines LPL11 and LPL21. According to one or more embodiments, the first voltage may be Vmax, and the voltage level of the first voltage may be twice the voltage level of the second voltage.

The second local plate line driver may apply the first voltage to a selected second local plate line in response to a selected first local plate line among the second local plate lines. In addition, the second local plate line driver may apply the second voltage to the other second local plate lines except for the selected second local plate line among the second local plate lines. Referring to FIG. 4, for example, when the selected first local plate line is the local plate line LPL31 connected to the memory cell MCa, the second memory cell is the memory cell MCb, and the selected second local plate line is the local plate line LPL32 connected to the memory cell MCb, the sub-plate line driver PDV32 may apply the first voltage to the local plate line LPL32. In addition, the sub-plate line drivers PDV12 and PDV22 may apply the second voltage to the local plate lines LPL12 and LPL22.

According to the operation of each of the first local plate line driver and the second local plate line driver, by decreasing the disturbance of the ferroelectric cell capacitors connected to the unselected local plate lines, the effect of maintaining the total charge of the corresponding ferroelectric cell capacitors and the operating performance of the FRAM and the reliability of data storage therein is improved.

Parasitic capacitors may also exist between the selected local plate lines and unselected local plate lines. In this case, the unselected local plate lines are arranged parallel to at least one word line (e.g., the word lines WLm−1 and WLm+1) adjacent to the selected word line (e.g., the word line WLm) in the third direction D3. Therefore, excessive disturbance may unintentionally occur in the ferroelectric cell capacitors of the memory cells connected to the adjacent word lines (e.g., the word lines WLm−1 and WLm+1), and the total charge of the ferroelectric cell capacitors may change.

In one or more embodiments, the memory cell array 110 may further include a third memory cell. The third memory cell may be connected to one unselected word line and third local plate lines. The third local plate lines may extend in the first direction D1 in which the word lines WLm−1, WLm, and WLm+1 extend and may be arranged parallel to the first local plate lines and the second local plate lines in the second direction D2 in which the bit lines extend. For example, when the word line WLm is a selected word line, the third memory cell may be a memory cell MCc or a memory cell MCd connected to the bit line BLi. However, the disclosure is not limited to the examples described above. For example, when the word line WLm is a selected word line, the third memory cell may be included in the memory cells connected to the word line WLm−1 or may be included in the memory cells connected to the word line WLm+1

In one or more embodiments, the local plate line drivers 153 may further include a third local plate line driver for one unselected word line. For example, the third local plate line driver may be connected to third local plate lines that are connected to the third memory cell. For example, when the third memory cell is the memory cell MCc, the third local plate line driver may include sub-plate line drivers PDV11, PDV21, and PDV31 connected to the local plate lines LPL11, LPL21, and LPL31 connected to the memory cell MCc. For example, when the third memory cell is the memory cell MCd, the third local plate line driver may include sub-plate line drivers PDV11, PDV21, and PDV31 connected to the local plate lines LPL11, LPL21, and LPL31 connected to the memory cell MCd. However, the disclosure is not limited to the examples described above, and the third local plate line driver may include sub-plate line drivers connected to any memory cell connected to the unselected word lines (e.g., the word lines WLm−1 and WLm+1).

The third local plate line driver may apply the third voltage (e.g., 0 V) lower than the second voltage to the third local plate lines.

In one or more embodiments, the third local plate lines for unselected word lines may be adjacent to the first local plate lines. For example, when the selected word line is the word line WLm and the unselected word line is the word line WLm−1 or the word line WLm+1, the third local plate lines may be local plate lines LPL11, LPL21, and LPL31 connected to the memory cell MCc or the memory cell MCd.

In one or more embodiments, the memory cell array 110 may further include a fourth memory cell. The fourth memory cell according to one or more embodiments may be connected to a selected word line, one bit line adjacent to the first bit line, and the first local plate lines. For example, referring to FIG. 4, when the first memory cell is the memory cell MCa, the fourth memory cell may be connected to the word line WLm and connected to the bit line BLi+1 adjacent to a bit line BLi.

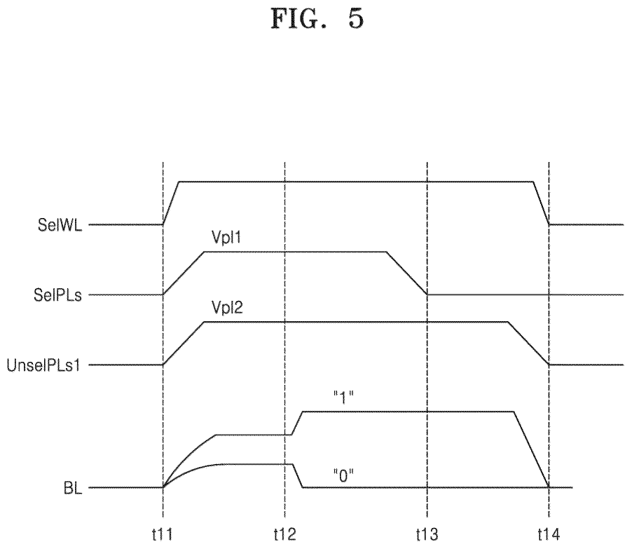

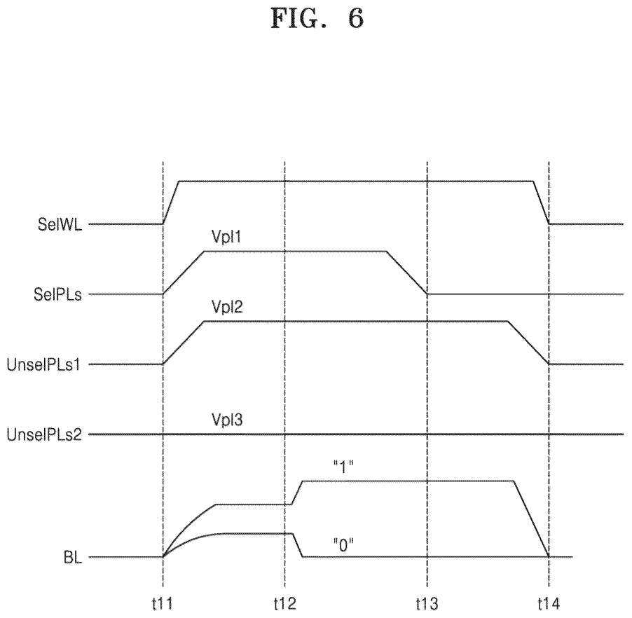

According to the operation of the third local plate line driver, there are effects of maintaining the total charge of the corresponding ferroelectric cell capacitors, improving the operating performance, improving the reliability of data, and reducing power consumption. FIGS. 5 and 6 are timing diagrams of signals for performing a read operation in the embodiment of FIG. 4. In FIGS. 5 to 9, it is assumed that a selected word line SelWL is the word line WLm. It is assumed that selected local plate lines SelPLs are the local plate line LPL31 connected to the memory cell MCa and the local plate line LPL32 connected to the memory cell MCb. It is assumed that first unselected local plate lines UnselPLs1 are the local plate lines LPL11 and LPL21 connected to the memory cell MCa and the local plate lines LPL12 and LPL22 connected to the memory cell MCb. It is assumed that second unselected local plate lines UnselPLs2 are the local plate lines LPL11, LPL21, LPL31, LPL12, LPL22, and LPL32 connected to memory cells connected to unselected word lines (e.g., word lines WLm−1 and WLm+1).

In one or more embodiments, the first local plate line driver may apply a first voltage Vpl1 to a selected first local plate line corresponding to the address ADDR among the first local plate lines during a first period. Also, the first local plate line driver may apply a second voltage Vpl2 to unselected first local plate lines during a second period. Here, the second period may be longer than the first period and may overlap partially the first period. The second local plate line driver may apply the first voltage Vpl1 to a selected second local plate line among the second local plate lines during the first period. Also, the second local plate line driver may apply the second voltage Vpl2 to the other unselected second local plate lines during the second period.

Referring to FIGS. 2 and 5, prior to first time t11, lines SelWL, SelPLs, UnselPLs1, and BL may be precharged to ground voltage (e.g., 0 V).

At first time t11, the selected word line SelWL may be activated. For example, a voltage having an activation level may be applied to the selected word line SelWL. The first voltage Vpl1 may be applied to the selected local plate lines SelPLs, and the second voltage Vpl2 may be applied to the first unselected local plate lines UnselPLs1. For example, the first voltage Vpl1 may be Vmax. The second voltage Vpl2 may be (½)*Vmax. However, the disclosure is not limited thereto. A voltage level of the bit line BL may rise. Here, the voltage level of the bit line BL when reading data “1” may rise more than that of data “0”. The total charges of the ferroelectric cell capacitors connected to the selected local plate lines SelPLs may be located at point a due to a potential difference between the selected local plate lines SelPLs and the bit line BL.

At second time t12, the voltage level of the bit line BL when reading data “1” may further rise. In this case, the potential difference between the selected local plate lines SelPLs and the bit line BL may gradually decrease to 0 V, and the total charges of the ferroelectric cell capacitors connected to the selected local plate lines SelPLs may be located at point b. The voltage level of the bit line BL when reading data “0 ” may decrease to the voltage level of the voltage (e.g., ground voltage) when precharged. In this case, the potential difference between the selected local plate lines SelPLs and the bit line BL may increase, and the total charges of the ferroelectric cell capacitors connected to the selected local plate lines SelPLs may be located at point a.

At third time t13, the voltage level of the selected local plate lines SelPLs may decrease to the voltage level of the ground voltage. The voltage level of the bit line BL when reading data “1” may be maintained at a constant voltage level and then decrease. In this case, the potential difference between the selected local plate lines SelPLs and the bit line BL may correspond to the voltage level of the reverse voltage, and the total charges of the ferroelectric cell capacitors connected to the selected local plate lines SelPLs may be located at point d. The voltage level of the bit line BL when reading data “0 ” may be maintained at the voltage level of the ground voltage. In this case, the potential difference between the selected local plate lines SelPLs and the bit line BL may gradually decrease and the total charges of the ferroelectric cell capacitors connected to the selected local plate lines SelPLs may be located at point b.

The first period according to one or more embodiments may be from first time t11 to third time t13. The second period may be from first time t11 to fourth time t14.

At fourth time t14, the selected word line SelWL, the local plate lines SelPLs and UnselPLs1 and the bit line BL may be precharged to the ground voltage.

Referring to FIGS. 2 and 6, the selected word line SelWL, the local plate lines SelPLs and UnselPLs1, and the bit line BL are the same as those described above with reference to FIG. 5, and therefore, the description thereof is omitted. In one or more embodiments, the first and second local plate line drivers may generate the first voltage Vpl1 and the second voltage Vpl2. The third local plate line driver may apply a third voltage Vpl3 to the second unselected local plate lines UnselPLs2.

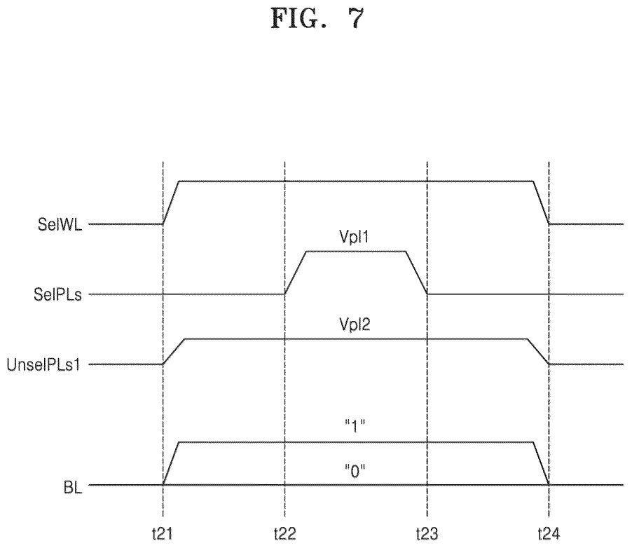

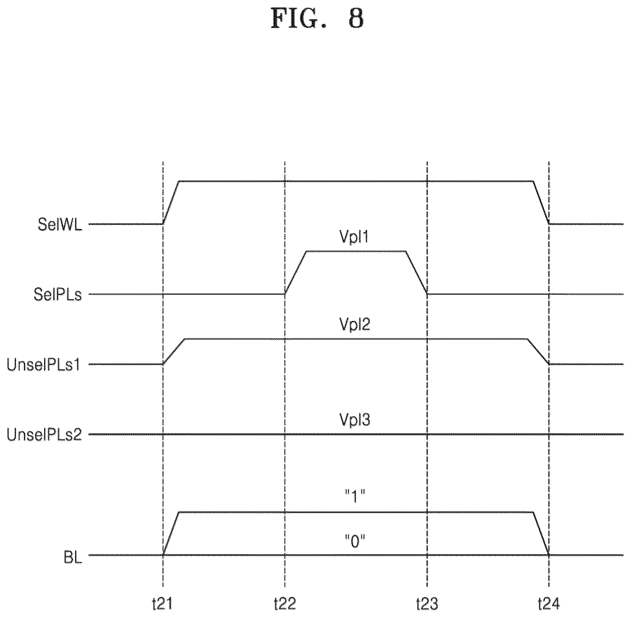

FIGS. 7 and 8 are timing diagrams of signals for performing a write operation in the embodiment of FIG. 4.

As described above, in the one or more embodiments, the first and second local plate line drivers may apply the first voltage Vpl1 to the selected first and second local plate lines during the first period. In addition, the first and second local plate line drivers may apply the second voltage Vpl2 to the unselected first and second local plate lines during the second period.

Referring to FIGS. 2 and 7, before first time t21, lines SelWL, SelPLs, and UnselPLs1, BL may be precharged. At first time t21, the selected word line SelWL may be activated. The second voltage Vpl2 may be applied to the first unselected local plate lines UnselPLs1. When data “1” is provided to the bit line BL, the total charges of the ferroelectric cell capacitors connected to the selected local plate lines SelPLs may be located at point d. When data “0”is provided to the bit line BL, the voltage level of the bit line BL may be 0 V.

At second time t22, the first voltage Vpl1 may be applied to the selected local plate lines SelPLs. When data “1” is provided to the bit line BL, the potential difference between the selected local plate lines SelPLs and the bit line BL may decrease to 0 V, and the total charges of the ferroelectric cell capacitors connected to the selected local plate lines SelPLs may be located at point e. When data “0 ” is provided to the bit line BL, the potential difference between the selected local plate lines SelPLs and the bit line BL may increase to Vmax, and the total charges of the ferroelectric cell capacitors connected to the selected local plate lines SelPLs may be located at point a.

At third time t23, the voltage level of the selected local plate lines SelPLs may be reduced to the voltage level of the ground voltage. When data “1” is provided to the bit line BL, the potential difference between the selected local plate lines SelPLs and the bit line BL may correspond to the voltage level of the reverse voltage, and the total charges of the ferroelectric cell capacitors connected to the selected local plate lines SelPLs may be located at point d. When data “0 ” is provided to the bit line BL, the potential difference between the selected local plate lines SelPLs and the bit line BL may gradually decrease to 0 V and the total charges of the ferroelectric cell capacitors connected to the selected local plate lines SelPLs may be located at point b.

At fourth time t24, lines SelWL, SelPLs, UnselPLs1, and BL may be precharged.

In one or more embodiments, the first period may be from second time t22 to third time t23, and the second period may be from first time t21 to fourth time t24.

Referring to FIGS. 2 and 8, the lines SelWL, SelPLs, UnselPLs1, and BL are as described above with reference to FIG. 7, and the second unselected local plate lines UnselPLs2 are the same as described above with reference to FIG. 6, and therefore, descriptions thereof are omitted.

FIG. 9 is a timing diagram of signals for performing a write operation according to one or more embodiments.

As described above, in one or more embodiments, the first and second local plate line drivers may apply the first voltage Vpl1 to the selected first and second local plate lines during the first period. In addition, the first and second local plate line drivers may apply the second voltage Vpl2 to the unselected first and second local plate lines during the second period. The write operation according to the embodiments illustrated in FIG. 9 may also be referred to as a dynamic random access memory (DRAM) write operation. The period from first time t1 to second time t2 may be a period during which a charge sharing operation and a sensing operation are performed, the period from second time t2 to third time t3 may be a period during which a read/write command is input, the period from third time t3 to fourth time t4 may be a period during which a restore (or re-write) operation is performed, and the period after fourth time t4 may be a period during which a precharge operation is performed.

Referring to FIG. 9, the selected word line SelWL may be activated from first time t1 to fourth time t4. During the first period from first time t1 to third time t3, the first voltage Vpl1 may be applied to the selected local plate lines SelPLs. During the second period from first time t1 to fourth time t4, the second voltage Vpl2 may be applied to the first unselected local plate lines UnselPLs1. The voltage level of the bit line BL may correspond to data “1” or data “0”. During the period from second time t2 to third time t3, a read command and/or a write command may be input sequentially, and if a write command is input, a bit line flip may occur in which the voltage level of the bit line BL changes. When third time t3 occurs while the voltage level of the bit line BL is maintained, the voltage applied to the bit line BL may be restored to the memory cell.

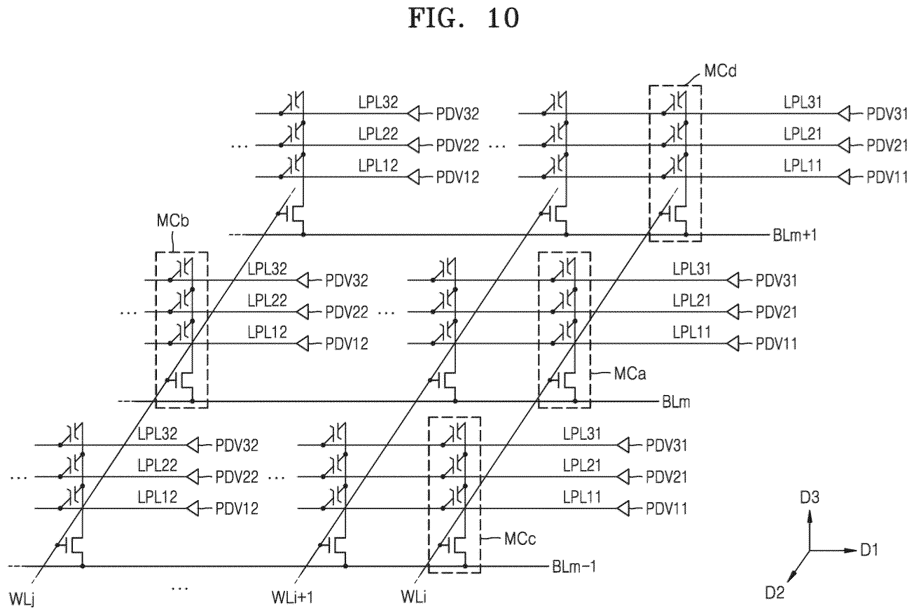

FIG. 10 is a diagram illustrating the memory cell array 110 including the memory cell MC of FIG. 3 and local plate lines and bit lines that are parallel to each other.

Referring to FIGS. 1 and 10, in one or more embodiments, the memory cell array 110 may include a plurality of bit lines BLm−1, BLm, and BLm+1 extending in the first direction D1, a plurality of word lines WLi, WLi+1, and WLj extending in the second direction D2, and a plurality of local plate lines LPL11, LPL12, LPL21, LPL22, LPL31, and LPL32 extending in the first direction D1. The number of each line in FIG. 10 is an example and may be greater than that shown in FIG. 10. The bit lines BLm−1, BLm, and BLm+1 may be arranged in parallel in the second direction D2. The bit line BLm may be adjacent to bit lines BLm−1 and BLm+1. The word lines WLi, WLi+1, and WLj may be arranged in parallel in the first direction D1. The word lines WLi and WLi+1 may be adjacent to each other. The local plate lines LPL11, LPL12, LPL21, LPL22, LPL31, and LPL32 may be arranged in parallel in the third direction D3.

In one or more embodiments, it is assumed that the memory cells included in the memory cell array 110 have a 1T3C structure as described above with reference to FIG. 4.

In one or more embodiments, the memory cell array 110 may include a first memory cell and a second memory cell connected to a first bit line among the bit lines BLm−1, BLm, and BLm+1. The first memory cell may be connected to a selected word line corresponding to the address ADDR among the word lines WLi, WLi+1, and WLj and first local plate lines. The second memory cell may be connected to an unselected word line among the word lines WLi, WLi+1, and WLj and second local plate lines. For example, when the first bit line is the bit line BLm and the selected word line is the word line WLi, the first memory cell may be the memory cell MCa and the second memory cell may be the memory cell MCb. The memory cell MCa may be connected to the word line WLi and the local plate lines LPL11, LPL21, and LPL31. The memory cell MCb may be connected to the word line WLj and the local plate lines LPL12, LPL22, and LPL32. The first and second memory cells may include one cell transistor and three ferroelectric cell capacitors. Descriptions thereof are the same as those given above with reference to FIG. 4.

In one or more embodiments, the local plate line drivers 153 may include at least two local plate line drivers, for example, first and second local plate line drivers, for one bit line. The number of memory cells receiving voltage from each of the first and second local plate line drivers may be one or more.

The first local plate line driver may be connected to local plate lines connected to the first memory cell, and the local plate lines connected to the first memory cell may extend in the first direction D1 and be arranged parallel to the bit lines BLm−1, BLm, and BLm+1. For example, when the first memory cell is the memory cell MCa, the first local plate line driver may include sub-plate line drivers PDV11, PDV21, and PDV31 connected to the local plate lines LPL11, LPL21, and LPL31 connected to the memory cell MCa.

The second local plate line driver may be connected to local plate lines connected to the second memory cell, and the local plate lines connected to the second memory cell may extend in the first direction D1 and arranged apart from the local plate lines connected to the first memory cell. For example, when the first memory cell is the memory cell MCa and the second memory cell is the memory cell MCb, the second local plate line driver may include the sub-plate line drivers PDV12, PDV22, and PDV32 connected to the local plate lines LPL12, LPL22, and LPL32 connected to the memory cell MCb.

In a structure in which the bit line is parallel to each local plate line as shown in FIG. 10, one local plate line connected to each of the memory cells of the selected word line may be selected. As described above, excessive disturbance of ferroelectric cell capacitors connected to unselected local plate lines may occur due to parasitic capacitors between local plate lines.

In one or more embodiments, the first local plate line driver may apply the first voltage Vpl1 to a selected first local plate line (e.g., the local plate line LPL31 connected to the memory cell MCa) corresponding to the address ADDR and may apply the second voltage Vpl2 to at least one unselected first local plate line (e.g., the local plate lines LPL11 and LPL12 connected to the memory cell MCa). The second local plate line driver may apply the second voltage to a plurality of second local plate lines (e.g., the local plate lines LPL12, LPL22, and LPL32 connected to the memory cell MCb).

In one or more embodiments, the memory cell array 110 may further include a third memory cell. The third memory cell may be connected to the selected word line, the second bit line, and the third local plate lines. The third local plate lines may extend in the first direction D1 and be arranged parallel to the first local plate lines and the second local plate lines in the second direction D2. For example, when the first and second memory cells are the memory cells MCa and MCb and the second bit line is one of the bit lines BLm−1 and BLm+1, the third memory cell may be one of the memory cells MCc and MCd.

In one or more embodiments, the local plate line drivers 153 may further include a third local plate line driver for the second bit line. For example, the third local plate line driver may be connected to third local plate lines that are connected to a third memory cell. For example, when the third memory cell is the memory cell MCc, the third local plate line driver may include the sub-plate line drivers PDV11, PDV21, and PDV31 connected to the local plate lines LPL11, LPL21, and LPL31 connected to the memory cell MCc. However, the disclosure is not limited to the examples described above. The third local plate line driver, like the first local plate line driver of FIG. 10, may select one local plate line among the third local plate lines.

In one or more embodiments, the second bit line (e.g., the bit line (BLm−1)) may be adjacent to the first bit line (e.g., the bit line BLm), and the third local plate lines may be adjacent to the first local plate lines.

Although the memory cells connected to the unselected word line WLi+1 may be in a floating state, because the first and third local plate line drivers apply the second voltage Vpl2 to the unselected local plate lines, the disturbance for the unselected word line WLi+1 may be reduced or stabilized.

In one or more embodiments, the memory cell array 110 may further include a fourth memory cell. The fourth memory cell may be connected to any unselected word line, the second bit line, and the fourth local plate lines. The fourth local plate lines may extend in the first direction D1 and be arranged parallel to the third direction D3, like the third local plate lines. For example, the fourth memory cell may be a memory cell other than the memory cells connected to the first to third local plate line drivers among the plurality of memory cells.

In one or more embodiments, the local plate line drivers 153 may further include a fourth local plate line driver for the second bit line. For example, the fourth local plate line driver may be connected to fourth local plate lines. The fourth local plate line driver may apply the third voltage Vpl3 to the fourth local plate lines.

According to the one or more embodiments described above, there is an effect of improving operating performance and data reliability, and reducing power consumption.

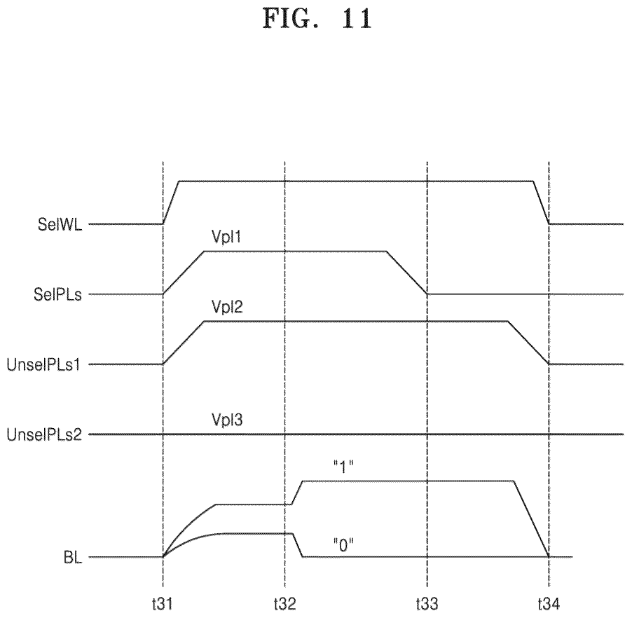

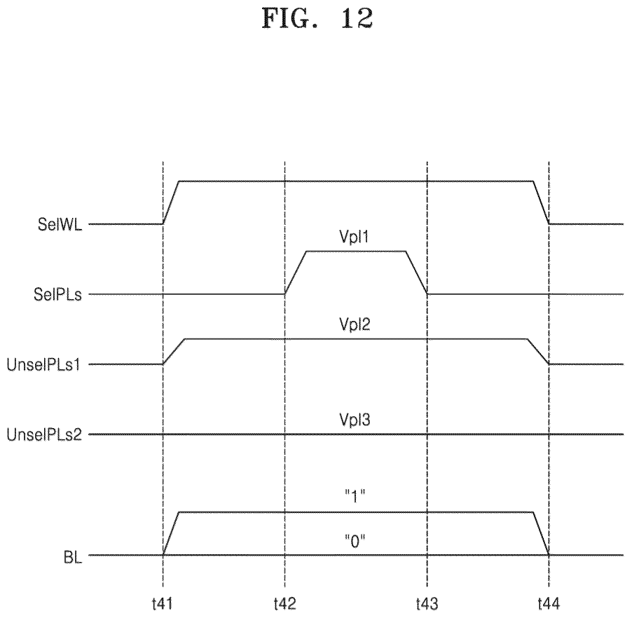

FIG. 11 is a timing diagram of signals for performing a read operation in the embodiment of FIG. 10. FIG. 12 is a timing diagram of signals for performing a write operation in the embodiment of FIG. 10.

In FIGS. 11 and 12, it is assumed that the bit line BL is a first bit line and is the bit line BLm. A selected word line SelWL is assumed to be the word line WLi. The selected local plate lines SelPLs may be arbitrarily determined in each of the first and third local plate line drivers, but for convenience, it is assumed that the selected local plate lines SelPLs are local plate lines LPL31 connected to each of the memory cells MCa, MCc, and MCd. It is assumed that the first unselected local plate lines UnselPLs1 are local plate lines LPL11 and LPL21 connected to each of the memory cells MCa, MCc, and MCd. It is assumed that the second unselected local plate lines UnselPLs2 are local plate lines LPL12, LPL22, and LPL32 connected to each of the memory cells connected to the unselected word line WLj.

The waveforms of the signals in the timing diagram illustrated in FIG. 11 may be as described above with reference to FIG. 6. The waveforms of the signals in the timing diagram illustrated in FIG. 12 may be as described above with reference to FIG. 8.

The memory cell array 110 and local plate line drivers 153 of FIG. 10 may apply the voltages Vpl1, Vpl2, and Vpl3 for performing a DRAM-oriented write operation for a certain period of time, as in the embodiments illustrated in FIG. 9.

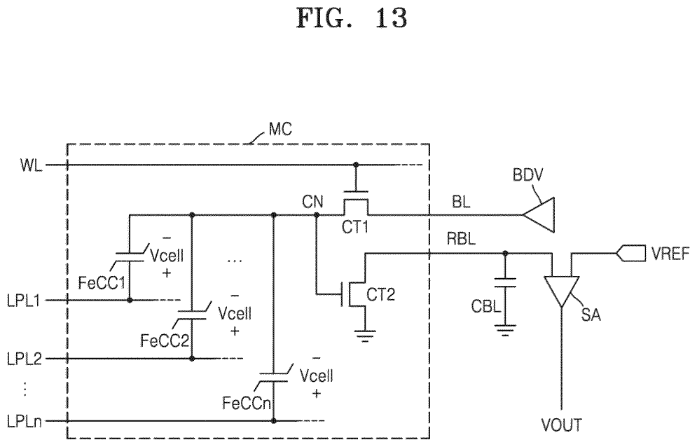

FIG. 13 is a circuit diagram of the memory cell MC, a bit line driver BPV, and the sense amplifier SA according to one or more embodiments.

Referring to FIG. 13, the memory cell MC according to one or more embodiments may have a structure of 2TnC and may include two transistors CT1 and CT2 and n ferroelectric cell capacitors FeCC1 to FeCCn. The cell transistor CT1 and n ferroelectric cell capacitors FeCC1 to FeCCn are as described above with reference to FIG. 3, and any additional redundant description is omitted.

The second electrode of the cell transistor CT1 may be connected to the bit line BL, and the bit line driver BDV may be connected to the bit line BL. The bit line driver BDV may provide the data DQ to the bit line BL when a write operation is performed.

The cell transistor CT2 may be turned on based on the voltage level of the node CN. At the node CN, a voltage generated based on the total charge C of a selected ferroelectric cell capacitor among n ferroelectric cell capacitors FeCC1 to FeCCn may be applied. The turned-on cell transistor CT2 may electrically connect the ground to the first input terminal of the sense amplifier SA. A gate electrode of the cell transistor CT2 may be connected to the node CN, a first electrode of the cell transistor CT2 may be connected to the ground, and a second electrode of the cell transistor CT2 may be connected to a read bit line RBL and the first input terminal of the sense amplifier SA. In one or more embodiments, the two transistors CT1 and CT2 may be implemented as n-type transistors, but are not limited thereto.

The first terminal of the parasitic capacitor CBL and the first input terminal of the sense amplifier SA may be connected to the read bit line RBL. The second terminal of the parasitic capacitor CBL may be connected to the ground. The second input terminal of the sense amplifier SA may be connected to a terminal to which the reference voltage VREF is applied. When a read operation is performed, the read bit line RBL may be precharged to a high voltage, and the sense amplifier SA may compare the voltage level of a voltage applied to the parasitic capacitor CBL with the voltage level of the reference voltage VREF and output an output voltage VOUT corresponding to data stored in the memory cell MC. For example, if the voltage applied to the parasitic capacitor CBL is less than the reference voltage VREF, the output voltage VOUT may correspond to data “1”. For example, if the voltage applied to the parasitic capacitor CBL is greater than the reference voltage VREF, the output voltage VOUT may correspond to data “0”. However, the disclosure is not limited thereto.

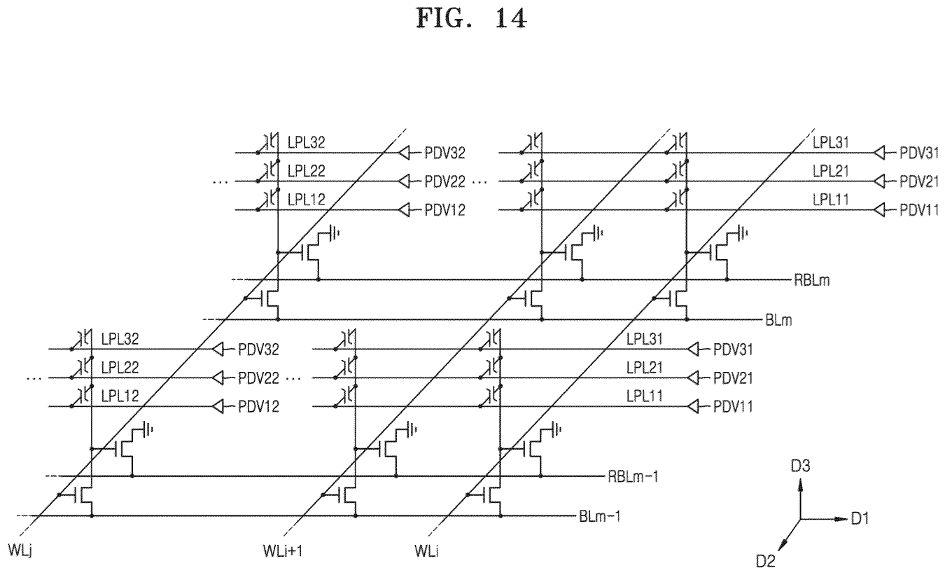

In one or more embodiments, n local plate lines LPL1 to LPLn connected to the memory cell MC may be parallel to a plurality of bit lines including the bit line BL. Memory cells in a structure in which n local plate lines LPL1 to LPLn are parallel to the bit line BL are described below with reference to FIG. 14.

FIG. 14 is a diagram illustrating the memory cell array 110 including the memory cells of FIG. 13 and local plate lines and bit lines that are parallel to each other. In the descriptions of the embodiment of FIG. 13, descriptions that are the same as those given above with reference to FIG. 10 are omitted.

Referring to FIGS. 1 and 14, in one or more embodiments, the memory cell array 110 may include a plurality of bit lines BLm−1, BLm, and BLm+1 extending in the first direction D1, a plurality of word lines WLi, WLi+1, and WLj extending in the second direction D2, and a plurality of local plate lines LPL11, LPL12, LPL21, LPL22, LPL31, and LPL32 extending in the first direction D1. The lines BLm−1, BLm, BLm+1, WLi, WLi+1, WLj, LPL11, LPL12, LPL21, LPL22, LPL31, and LPL32 shown in FIG. 14 are as shown in FIG. 9. The memory cell array 110 may further include a plurality of read bit lines RBLm−1, RBLm, and RBLm+1 extending in the first direction D1. The read bit lines RBLm−1, RBLm, and RBLm+1 may be arranged in parallel in the second direction D2.

In one or more embodiments, the memory cells included in the memory cell array 110 may have a 2TnC structure as described above with reference to FIG. 13. For example, the memory cells included in the memory cell array 110 may have a 2T3C structure. However, the number of ferroelectric cell capacitors may be two or four or more.

In one or more embodiments, as described above with reference to FIG. 13, the first memory cell included in the memory cell array 110 may include first and second cell transistors, and first ferroelectric cell capacitors. The second memory cell included in the memory cell array 110 may include third and fourth cell transistors and second ferroelectric cell capacitors.

In a structure in which the bit line is parallel to each local plate line as shown in FIG. 14, the voltage provided to the local plate line may be applied to be different depending on data “1”and data “0”.

In one or more embodiments, during a first period, the first local plate line driver may apply a read voltage to a selected first local plate line corresponding to the address ADDR and may apply the third voltage Vpl3 to at least one unselected first local plate line. The second local plate line driver may apply the third voltage Vpl3 that is lower than the read voltage to the second local plate lines.

In one or more embodiments, during a second time period after the first period, the first local plate line driver may apply the second voltage Vpl2 to at least one unselected first local plate line.

In one or more embodiments, the local plate line drivers 153 may further include a third local plate line driver. The third local plate line driver may be connected to third local plate lines. The third local plate lines may extend in the first direction D1 and arranged parallel to the first local plate lines and the second local plate lines in the second direction D2. The memory cell array 110 may further include a third memory cell. The third memory cell may be connected to a selected word line (e.g., the word line WLi), a second bit line (e.g., one of the bit lines BLm−1 and BLm+1), and third local plate lines.

In one or more embodiments, during the first period, the third local plate line driver may apply a read voltage to a selected third local plate line corresponding to the address ADDR and may apply the third voltage Vpl3 lower than the read voltage to at least one unselected third local plate line. In addition, during the second period after the first period., the third local plate line driver may apply the second voltage Vpl2 to at least one unselected third local plate line.

In one or more embodiments, the second bit line may be adjacent to the first bit line.

In one or more embodiments, similarly to that described above with reference to FIG. 10, the local plate line drivers 153 may further include the fourth local plate line driver connected to the fourth local plate lines. The memory cell array 110 may further include the fourth memory cell. The fourth memory cell may be any memory cell other than the memory cells connected to the first to third local plate line drivers among the memory cells.

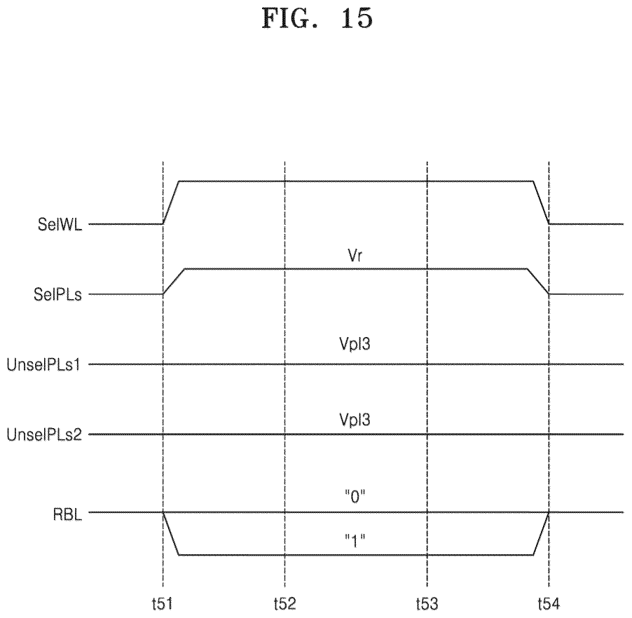

FIG. 15 is a timing diagram of signals for performing a read operation in the embodiment of FIG. 14. In the descriptions of the embodiment illustrated in FIG. 15, descriptions that are the same as those given above are omitted.

In FIG. 15, it is assumed that the bit line BL is the first bit line and is the bit line BLm. It is assumed that the selected word line SelWL is the word line WLi. The selected local plate lines SelPLs may be arbitrarily determined by each of the first and third local plate line drivers, but for convenience, it is assumed that they are local plate lines LPL31 connected to each of the memory cells connected to the word line WLi. It is assumed that the first unselected local plate lines UnselPLs1 are local plate lines LPL11 and LPL21 connected to each of the memory cells connected to the word line WLi. It is assumed that the second unselected local plate lines UnselPLs2 are local plate lines LPL12, LPL22, and LPL32 connected to each of the memory cells connected to the unselected word line WLj. It is assumed that the read bit line RBL is the read bit line RBLm.

Referring to FIG. 15, before first time t51, the read bit line RBL may be precharged to a high voltage. During a period from first time t51 to fourth time t54, the selected word line SelWL may be activated and the voltage level of the selected local plate line SelPL may be maintained at the voltage level of the read voltage Vr. The third voltage Vpl3 may be applied to the first unselected local plate lines UnselPLs1 and the second unselected local plate lines UnselPLs2. The voltage level of the read bit line RBL when reading data “0 ” may be maintained at a high voltage. The voltage level of the read bit line RBL when reading data “1” may be reduced to and maintained at aground voltage.

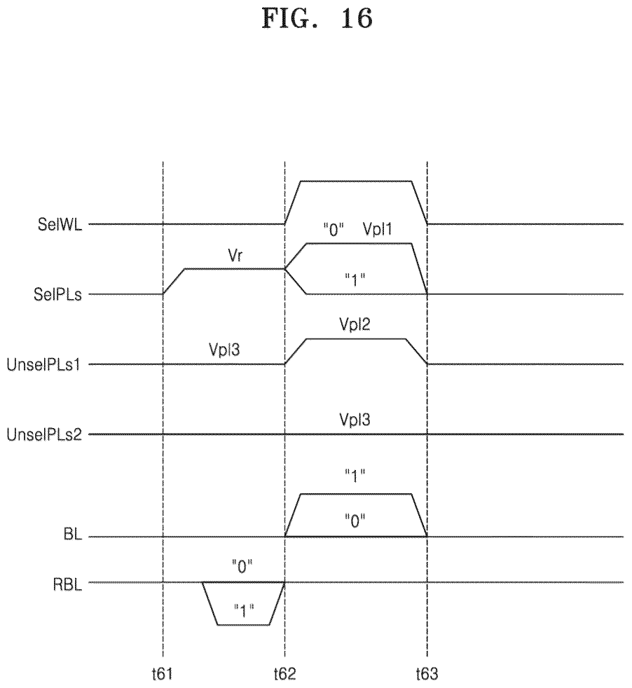

FIG. 16 is a timing diagram of signals for performing a write operation in the embodiment of FIG. 14. The assumptions of the lines SelWL, SelPLs, UnselPLs1, UnselPLs2, BL, and RBL shown in FIG. 16 are the same as those assumed in FIG. 15. In the descriptions of the embodiment of FIG. 16, descriptions that are the same as those given above are omitted.

In one or more embodiments, during the first period, a read voltage Vr may be applied to the selected local plate line SelPL. The third voltage Vpl3 may be applied to the first unselected local plate lines UnselPLs1. The first period may be from first time t61 to second time t62. The voltage level of the read bit line RBL between first time t61 and second time t62 is as described above with reference to FIG. 15. At second time t62, the read bit line RBL may be precharged to a high voltage. During the second period after the first period, the first voltage Vpl1 or ground voltage may be applied to the selected local plate line SelPL. When data “1” is written, the ground voltage may be applied, and when data “0 ” is written, the first voltage Vpl1 may be applied. During the second period, the second voltage Vpl2 may be applied to the first unselected local plate lines UnselPLs1. The second period may be from the second hour t62 to the third hour t63. The third voltage Vpl3 may be applied to the second unselected local plate lines UnselPLs2. After third time t63, lines SelWL, SelPLs, UnselPLs1, UnselPLs2, and BL may be precharged.

The memory cell array 110 and local plate line drivers 153 of FIG. 14 may apply the voltages Vpl1, Vpl2, and Vpl3 for performing a DRAM-oriented write operation for a certain period of time, as in the embodiments illustrated in FIG. 9.

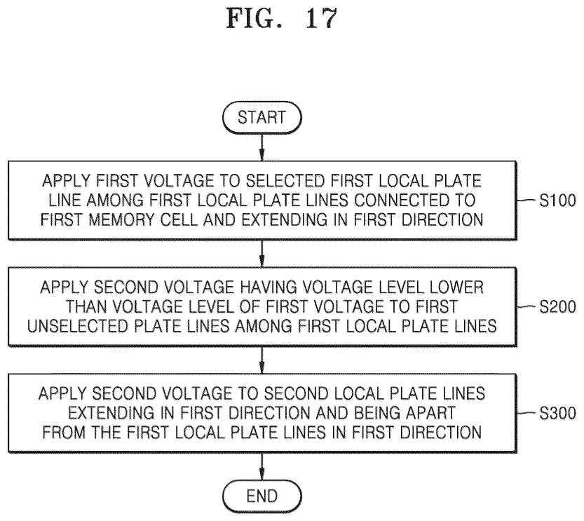

FIG. 17 is a flowchart of an operating method of a nonvolatile memory device according to one or more embodiments.

Referring to FIG. 17, an operation (S100) of applying the first voltage to a selected first local plate line among the first local plate lines connected to the first memory cell and extending in the first direction is performed. An operation (S200) of applying the second voltage having the voltage level lower than the voltage level of the first voltage to first unselected plate lines among the first local plate lines is performed. An operation (S300) of applying the second voltage to the second local plate lines extending in the first direction and being apart from the first local plate lines in the first direction is performed. Operations S100 to S300 may correspond to the one or more embodiments described above with reference to FIGS. 1 to 16.

At least one of the components, elements, modules, units, or the like (collectively “components” in this paragraph) represented by a block or an equivalent indication (collectively “block”) in the above embodiments including the drawings such as FIGS. 1, 3, 4, 10, 13 and 14, for example, address buffer, address decoder, drivers, sense amplifiers, controller, flip-flop, latch, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

It will be apparent to those skilled in the art that the structure of the disclosure may be variously modified or changed without departing from the technical spirit of the disclosure. In view of the above, it is intended that the disclosure cover modifications and variations of the disclosure if they fall within the scope of the claims below and their equivalents.

Although specific terms have been used to describe one or more embodiments in this specification, they have been used only for the purpose of describing the disclosure and are not intended to limit the meaning or the scope of the disclosure set forth in the claims. Therefore, a person skilled in the art will understand that various modifications and equivalent other embodiments are made therefrom. Therefore, the true technical protection scope of the disclosure should be determined by the technical idea of the appended claims.

What is claimed is:

1. A nonvolatile memory device comprising:
a memory cell array comprising a first memory cell and a second memory cell, wherein the first memory cell and the second memory cell are connected to a selected word line among a plurality of word lines, wherein the selected word line corresponds to an address, and wherein the plurality of word lines extend in a first direction;
a first local plate line driver connected to a plurality of first local plate lines, wherein the plurality of first local plate lines extend in the first direction; and
a second local plate line driver connected to a plurality of second local plate lines, wherein the plurality of second local plate lines extend in the first direction and are separated from the plurality of first local plate lines in the first direction,
wherein the first memory cell is connected to a first bit line among a plurality of bit lines and to the plurality of first local plate lines, and
wherein the second memory cell is connected to a second bit line among the plurality of bit lines and to the plurality of second local plate lines.

2. The nonvolatile memory device of claim 1,
wherein the first memory cell comprises:
a first cell transistor comprising a gate electrode connected to the selected word line, wherein the first cell transistor is connected to the first bit line and a first node; and
a plurality of first ferroelectric cell capacitors connected to the first node and respectively connected to the plurality of first local plate lines, and
wherein the second memory cell comprises:
a second cell transistor comprising a gate electrode connected to the selected word line, wherein the second cell transistor is connected to the second bit line and a second node; and
a plurality of second ferroelectric cell capacitors connected to the second node and respectively connected to the plurality of second local plate lines.

3. The nonvolatile memory device of claim 1,
wherein the first local plate line driver is configured to:
apply a first voltage to a selected first local plate line corresponding to the address, from among the plurality of first local plate lines, and
apply a second voltage lower than the first voltage to at least one unselected first local plate line, from among the plurality of first local plate lines, and
wherein the second local plate line driver is configured to:
apply the first voltage to a second local plate line corresponding to the selected first local plate line, from among the plurality of second local plate lines, and
apply the second voltage to at least one unselected second local plate line, from among the plurality of second local plate lines.

4. The nonvolatile memory device of claim 1,
wherein the plurality of bit lines extend in a second direction,
wherein the nonvolatile memory device further comprises:
a third local plate line driver connected to a plurality of third local plate lines, wherein the plurality of third local plate lines extend in the first direction and are offset from the plurality of first local plate lines and the plurality of second local plate lines in the second direction, and
wherein the memory cell array further comprises a third memory cell connected to an unselected word line among the plurality of word lines and to the plurality of third local plate lines.

5. The nonvolatile memory device of claim 4,
wherein the first local plate line driver is configured to:
apply a first voltage to a selected first local plate line corresponding to the address, from among the plurality of first local plate lines, during a first period, and
apply a second voltage lower than the first voltage to at least one unselected first local plate line, from among the plurality of first local plate lines, during a second period longer than the first period,
wherein the second local plate line driver is configured to:
apply the first voltage to a second local plate line corresponding to the selected first local plate line, from among the plurality of second local plate lines, during the first period, and
apply the second voltage to at least one unselected second local plate line, from among the plurality of second local plate lines, during the second period, and
wherein the third local plate line driver is configured to apply a third voltage lower than the second voltage to the plurality of third local plate lines.

6. The nonvolatile memory device of claim 5, wherein the first voltage is double the second voltage.

7. The nonvolatile memory device of claim 6, wherein the third voltage is a ground.

8. The nonvolatile memory device of claim 4,
wherein the unselected word line is adjacent to the selected word line, and
wherein the plurality of third local plate lines are adjacent to the plurality of first local plate lines.

9. The nonvolatile memory device of claim 1, wherein the memory cell array further comprises a fourth memory cell connected to the selected word line, one of the plurality of bit lines adjacent to the first bit line, and the plurality of first local plate lines.

10. A nonvolatile memory device comprising:
a memory cell array comprising a first memory cell and a second memory cell, wherein the first memory cell and the second memory cell are connected to a first bit line among a plurality of bit lines, and wherein the plurality of bit lines extend in a first direction;
a first local plate line driver connected to a plurality of first local plate lines, wherein the plurality of first local plate lines extend in the first direction; and
a second local plate line driver connected to a plurality of second local plate lines, wherein the plurality of second local plate lines extend in the first direction and are separated from the plurality of first local plate lines in the first direction,
wherein the first memory cell is connected to a selected word line among a plurality of word lines and to the plurality of first local plate lines,
wherein the selected word line corresponds to an address, and
wherein the second memory cell is connected to a first unselected word line among the plurality of word lines and to the plurality of second local plate lines.

11. The nonvolatile memory device of claim 10,
wherein the first memory cell comprises:
a first cell transistor comprising a gate electrode connected to the selected word line, wherein the first cell transistor is connected to the first bit line and a first node; and
a plurality of first ferroelectric cell capacitors connected to the first node and respectively connected to the plurality of first local plate lines, and
wherein the second memory cell comprises:
a second cell transistor comprising a gate electrode connected to the first unselected word line, wherein the second cell transistor is connected to the first bit line and a second node; and
a plurality of second ferroelectric cell capacitors connected to the second node and respectively connected to the plurality of second local plate lines.

12. The nonvolatile memory device of claim 11,
wherein the first local plate line driver is configured to:
apply a first voltage to a selected first local plate line corresponding to the address, from among the plurality of first local plate lines, and
apply a second voltage lower than the first voltage to at least one unselected first local plate line, from among the plurality of first local plate lines, and
wherein the second local plate line driver is configured to apply the second voltage to the plurality of second local plate lines.

13. The nonvolatile memory device of claim 10,
wherein the first memory cell comprises:
a first cell transistor comprising a gate electrode connected to the selected word line, wherein the first cell transistor is connected to the first bit line and a first node;
a second cell transistor comprising a gate electrode connected to the first node, wherein the second cell transistor is connected to a first read bit line corresponding to the first bit line, from among a plurality of read bit lines, and to a ground; and
a plurality of first ferroelectric cell capacitors connected to the first node and respectively connected to the plurality of first local plate lines, and
wherein the second memory cell comprises:
a third cell transistor comprising a gate electrode connected to the first unselected word line, wherein the third cell transistor is connected to the first bit line and a second node;
a fourth cell transistor comprising a gate electrode connected to the second node, wherein the fourth cell transistor is connected to the first read bit line and the ground; and
a plurality of second ferroelectric cell capacitors connected to the second node and respectively connected to the plurality of second local plate lines.

14. The nonvolatile memory device of claim 13,
wherein the first local plate line driver is configured to:
apply a read voltage to a selected first local plate line corresponding to the address, from among the plurality of first local plate lines, during a first period, and
apply a third voltage lower than the read voltage to at least one unselected first local plate line, from among the plurality of first local plate lines, during the first period, and
wherein the second local plate line driver is configured to apply the third voltage to the plurality of second local plate lines.

15. The nonvolatile memory device of claim 14, wherein the first local plate line driver is configured to apply a second voltage higher than the third voltage to the at least one unselected first local plate line, during a second period after the first period.

16. The nonvolatile memory device of claim 10,
wherein the plurality of word lines extend in a second direction,
wherein the nonvolatile memory device further comprises:
a third local plate line driver connected to a plurality of third local plate lines, wherein the plurality of third local plate lines extend in the first direction and are offset from the plurality of first local plate lines and the plurality of second local plate lines in the second direction, and
wherein the memory cell array further comprises a third memory cell connected to the selected word line, a second bit line among the plurality of bit lines, and the plurality of third local plate lines.

17. The nonvolatile memory device of claim 16,
wherein the third local plate line driver is configured to:
apply a read voltage to a selected third local plate line corresponding to the address, from among the plurality of third local plate lines, during a first period,
apply a third voltage lower than the read voltage to at least one unselected third local plate line, from among the plurality of third local plate lines, during the first period, and
apply a second voltage higher than the third voltage and lower than a first voltage to the at least one unselected third local plate line, during a second period after the first period.

18. The nonvolatile memory device of claim 10,
wherein the plurality of word lines extend in a second direction,
wherein the nonvolatile memory device further comprises:
a fourth local plate line driver connected to a plurality of fourth local plate lines, wherein the plurality of fourth local plate lines extend in the first direction and are offset from the plurality of first local plate lines and the plurality of second local plate lines in the second direction, and
wherein the memory cell array further comprises a fourth memory cell connected to a second unselected word line among the plurality of word lines, a second bit line among the plurality of bit lines, and the plurality of fourth local plate lines.

19. The nonvolatile memory device of claim 18, wherein the fourth local plate line driver is configured to apply a ground voltage level to the plurality of fourth local plate lines.

20. A method of operating a nonvolatile memory device including a plurality of memory cells, the method comprising:
applying a first voltage to a selected first local plate line, from among a plurality of first local plate lines of the nonvolatile memory device, wherein the plurality of first local plate lines extend in a first direction and are connected to a first memory cell among the plurality of memory cells;
applying a second voltage lower than the first voltage to a first unselected plate line, from among the plurality of first local plate lines; and
applying the second voltage to a plurality of second local plate lines of the nonvolatile memory device, wherein the plurality of second local plate lines extend in the first direction and are separated from the plurality of first local plate lines in the first direction.
